(19) United States
(12) Patent Application Publication
(10) Pub. No.: US 2015/0318287 A1
(43) Pub. Date: Nov. 5, 2015

(54) SEMICONDUCTOR DEVICE, AND MANUFACTURING FOR SAME

(71) Applicant: Kenichi SUGINO, (US)

(72) Inventor: Kenichi Sugino, Tokyo (JP)

(21) Appl. No.: 14/651,646

(22) PCT Filed: Dec. 6, 2013
(86) PCT No.: PCT/JP2013/082756

§ 371 Date: Jun. 11, 2015

(30) Foreign Application Priority Data
Dec. 14, 2012 (JP) 2012-273329

(51) Int. Cl. H01L 27/108; H01L 23/532; H01L 21/311; H01L 23/528

(52) U.S. Cl. CPC H01L 27/10894; H01L 27/10885; H01L 23/528; H01L 23/53261; H01L 23/53209; H01L 27/10876; H01L 27/10823; H01L 27/10814; H01L 27/10897; H01L 21/31116; H01L 27/10888

(57) ABSTRACT

A semiconductor device comprising: a semiconductor substrate; a first wiring having, in this order, on a first region of a semiconductor substrate, a second silicon film containing impurity, and a conductive film; and a second wiring having, in this order, on a second region of a semiconductor substrate, a first silicon film containing impurity, an etching stop film, a second silicon film containing impurity, and a conductive film.

### TECHNICAL FIELD

The present invention relates to a semiconductor device and method of manufacture thereof.

### BACKGROUND ART

One type of semiconductor device is constituted by a DRAM (Dynamic Random Access Memory); this comprises a memory cell region provided with word lines and bit lines, and a peripheral circuit region for driving the memory cells.

Patent Reference 1 (Tokkai 2011-129771) discloses a DRAM in which, in order to meet demands for miniaturization, memory cells are constituted by word lines that are embedded within a semiconductor substrate and bit lines that are arranged on the upper surface of the semiconductor substrate. FIG. 15 to FIG. 18 of Patent Reference 1 disclose a method of forming the gate electrodes of a planar transistor in the peripheral circuit region, using the same step as the step of forming the bit lines in the memory cell region. Specifically, a silicon film 78B, a metal film 79, and a silicon nitride film 80 are formed in laminated fashion in the memory cell region of FIG. 17(A), and a silicon film 306, a metal film 79 and a silicon nitride film 80 are formed in the peripheral circuit region of FIG. 17(D) by the same step. After this, bit lines 81 are formed in the memory cell region of FIG. 17(B) using a lithographic method and dry etching method and gate electrodes 310 of planar transistors constituting the peripheral circuit region are simultaneously formed in FIG. 17(E).

### PATENT REFERENCES

Patent Reference 1: Tokkai 2011-129771

### Outline of the Invention

### Problem that the Invention is Intended to Solve

In the prior art disclosed in the above Patent Reference 1, a dry etching step is performed in which the same material is deposited in the memory cell region and the peripheral circuit region and the bit lines are formed in the memory cell region while gate electrodes are simultaneously formed in the peripheral circuit region. However, there was the problem that, in this dry etching step, there was unexpected etching of the semiconductor substrate around the gate electrodes of the peripheral circuit region. Also, there was the problem that, if the silicon film of the peripheral circuit region was constituted by a two-layer laminated film, some of this film was left behind when etching was carried out.

FIGS. 18A, 18B and 18C show similar layouts corresponding to FIGS. 17(A), (D) and (E) disclosed in Patent Reference 1. FIG. 18A is a cross-sectional view of the memory cell region and FIGS. 18B and 18C respectively show cross-sections in different directions of the peripheral circuit region. A more detailed description of the problems of the prior art is given below with reference to FIGS. 18A, 18B and 18C.

As shown in FIG. 18A, in the memory cell region, a laminated film consisting of an interlayer insulating film 75, a silicon film 78B, a metal (tungsten: W) film 79, and a silicon nitride film 80 is formed on the semiconductor substrate 100, which is formed with an element isolating region 200 and embedded gate electrodes 300. In contrast, as shown in FIG. 18B, in the peripheral circuit region, a laminated film constituted by a first silicon film 300, second silicon film 78A, metal (tungsten: W) film 79 and silicon nitride film 80 is formed, with interposition of a gate insulating film 501, on the semiconductor substrate 100, which is formed with an element isolating region 200. The silicon film 78B of the memory cell region and the second silicon film 78A of the peripheral circuit region are formed simultaneously, with the same film thickness.

As described above, in the memory cell region, an interlayer insulating film 75 is formed below the silicon film 78B. However, an interlayer insulating film cannot be formed in the peripheral circuit region, for reasons concerned with the formation of the transistors. Consequently, in the peripheral circuit region, the first silicon film 300 constituting the gate electrodes is formed beforehand with a thickness corresponding to the film thickness of the interlayer insulating film 75 of the memory cell region. In this way, it is arranged that no step is generated between the memory cell region and the peripheral circuit region. The purpose of this is to avoid the problem of disconnection of the metal film 79 at this step, if such a step were to be formed by the memory cell region and peripheral circuit region. Subsequently, the bit lines are formed in the memory cell region and, simultaneously, the gate electrodes are formed in the peripheral circuit region, by performing lithographic processing and dry etching processing of the laminated film of the memory cell region and peripheral circuit region.

However, with increasing miniaturization of DRAMs, in the aforementioned dry etching processing, the etching rate density difference between the dense pattern of bit lines formed in the memory cell region and the isolated patterns of the gate electrodes formed in the peripheral circuit region becomes large, making such processing difficult. In other words, the etching rate in respect of the isolated patterns of the peripheral circuit region is faster than the etching rate of the dense pattern of the memory cell region. Also, in etching of the silicon nitride film 80, W film 79, and silicon films 78B, 78A and 300, in each case, a fluorine-containing plasma is employed originating from sulfur hexafluoride (SF₆), carbon tetrafluoride (CF₄) or trifluoromethane (CHF₃) gas, so it is difficult to secure etching selectivity between materials. Consequently, while etching the laminated film in the memory cell region, undesired etching of the silicon nitride film 80, W film 79 and silicon films 78A, and 300 of the peripheral circuit region also occurred; furthermore, over-etching of the exposed gate insulating film 501 was produced. Since the film thickness of the gate insulating film 501 is small, at about 4 nm, the problem arose that, as shown in FIG. 18C, in the peripheral circuit region, the gate insulating film 501 was removed, resulting in substrate damage D2 where the exposed semiconductor substrate 100 was further removed.

Also, the silicon film of the peripheral circuit region consists of a laminated film of two layers, namely, the first silicon film 300 and second silicon film 78A. Consequently, at the interface of the first silicon film 300 and second silicon film 78A, sometimes an intervening layer D3 was produced that impeded dry etching. In this case, the problem was produced of generation of a silicon residue D1 on the gate insulating film 501.

These problems caused short-circuiting or disconnection of the wiring, degrading the electrical performance and so adversely affecting the performance of the semiconductor device.

### Means for Solving the Problem

An embodiment relates to a semiconductor device having:

a semiconductor substrate;
a first wiring comprising, in this order, a second silicon film containing impurity and a conductive film, on a first region of said semiconductor substrate; and
a second wiring comprising, in this order, a first silicon film containing impurity, an etching stop film, a second silicon film containing impurity, and a conductive film, on a second region of said semiconductor substrate.

Another embodiment relates to a method of manufacturing a semiconductor device having:

a step of forming, in this order, a first silicon film containing impurity and an etching stop film on the second region of said semiconductor substrate;
a step of forming, in this order, a second silicon film containing impurity and a conductive film on the first and second regions of said semiconductor substrate;
a step of forming the first wiring having said second silicon film and conductive film in said first region, by etching the conductive film and said second silicon film of said first and second regions until said etching stop film is exposed;
a step of etching said etching stop film of said second region; and
a step of forming a second wiring having said second silicon film, conductive film, etching stop film and first silicon film in said second region, by etching said first silicon film of said second region.

### Beneficial Effect of the Invention

A semiconductor device of excellent device performance can be provided.

### BRIEF DESCRIPTION OF THE DRAWINGS

FIG. 1 This is a cross-sectional view showing the layout of major parts according to an example of a semiconductor device according to the present invention.

FIG. 2 This is a plan view showing a semiconductor device according to a first embodiment.

FIG. 3 This is a cross-sectional view showing a semiconductor device according to the first embodiment.

FIG. 4 This is a view showing a method of manufacturing a semiconductor device according to the first embodiment.

FIG. 5 This is a cross-sectional view showing a method of manufacturing a semiconductor device according to the first embodiment.

FIG. 6 This is a cross-sectional view showing a method of manufacturing a semiconductor device according to the first embodiment.

FIG. 7 This is a cross-sectional view showing a method of manufacturing a semiconductor device according to the first embodiment.

FIG. 8 This is a cross-sectional view showing a method of manufacturing a semiconductor device according to the first embodiment.

FIG. 9 This is a cross-sectional view showing a method of manufacturing a semiconductor device according to the first embodiment.

FIG. 10 This is a cross-sectional view showing a method of manufacturing a semiconductor device according to the first embodiment.

FIG. 11 This is a cross-sectional view showing a method of manufacturing a semiconductor device according to the first embodiment.

FIG. 12 This is a cross-sectional view showing a method of manufacturing a semiconductor device according to the first embodiment.

FIG. 13 This is a cross-sectional view showing a method of manufacturing a semiconductor device according to the first embodiment.

FIG. 14 This is a cross-sectional view showing a method of manufacturing a semiconductor device according to the first embodiment.

FIG. 15 This is a cross-sectional view showing a method of manufacturing a semiconductor device according to the first embodiment.

FIG. 16 This is a cross-sectional view showing a method of manufacturing a semiconductor device according to the first embodiment.

FIG. 17 This is a cross-sectional view showing a method of manufacturing a semiconductor device according to the first embodiment.

FIG. 18 This is a view given in explanation of the problems of a semiconductor device according to the prior art.

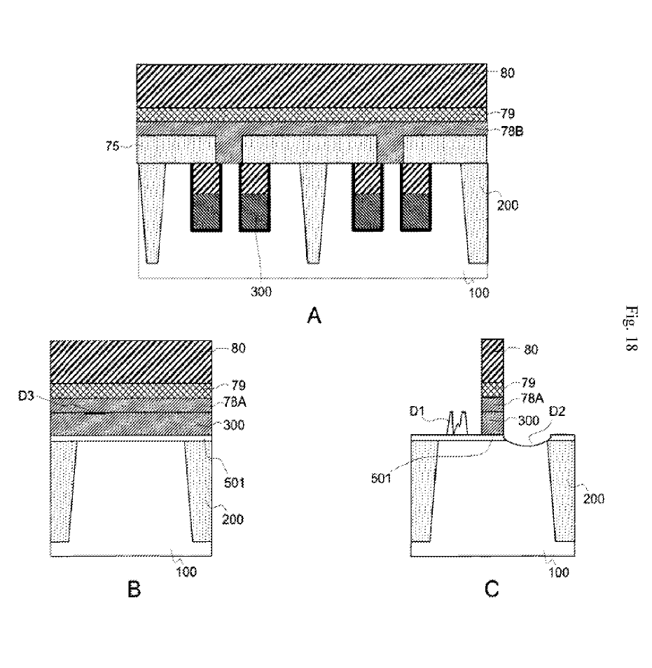

### MODES OF PUTTING THE INVENTION INTO EFFECT

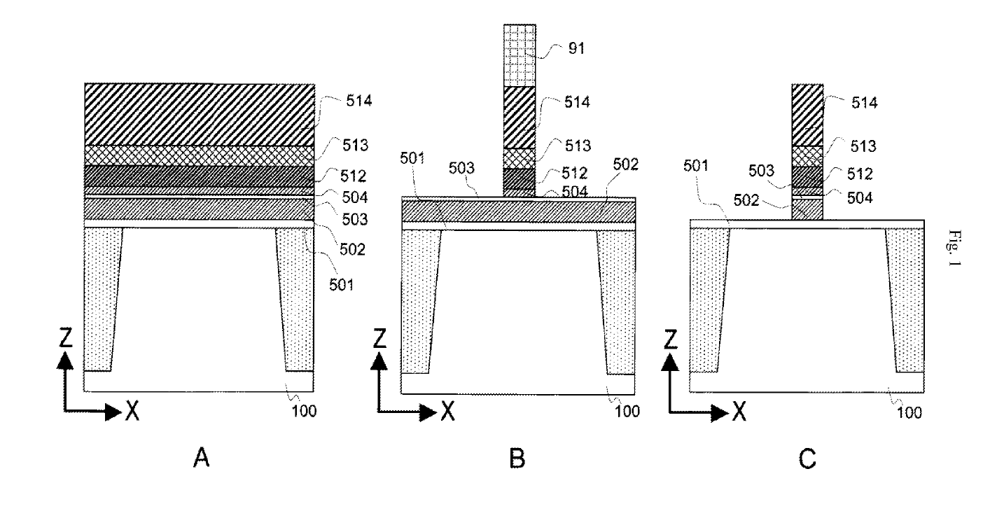

In order to solve the aforementioned problems, the present invention is constituted by providing an etching stop film having etching resistance between a step compensation first silicon film and a second silicon film formed in a second region (for example a peripheral circuit region). Hereinbelow, a construction according to the present invention will be described by way of example with reference to FIG. 1.

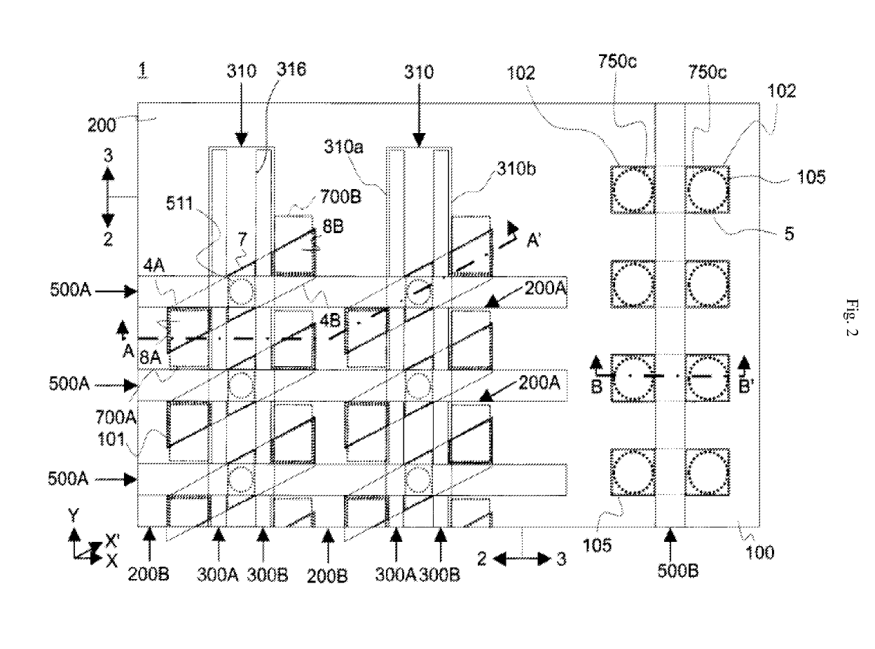

FIG. 1 is a view showing the layout of major parts of a semiconductor device according to an example of the present invention; FIG. 1A, FIGS. 1B and 1C are respectively cross-sectional views of a peripheral circuit region (second region), being views corresponding to a cross-section in the direction B-B′ of FIG. 2. Also, FIG. 1A, FIG. 1B and FIG. 1C respectively represent the peripheral circuit region at respectively different manufacturing stages: the steps are executed in the order FIG. 1A, FIG. 1B and FIG. 1C.

Specifically, as shown in FIG. 1A, a gate insulating film 501 is formed on the semiconductor substrate 100. Next, on this gate insulating film 501, there are formed, in this order, a first silicon film 502, an etching stop film 503, a second silicon film 504, a first conductive film 512, a second conductive film 513 and a cover insulating film 514. For the etching stop film 503, there is formed a film of high etching resistance in dry etching, using a fluorine-containing plasma originating from the etching gas that is employed, such as sulfur hexafluoride (SF₆) gas, carbon tetrafluoride (CF₄) gas or trifluoromethane (CHF₃) gas. Specifically, as the etching stop film 503, there may be employed a single-layer film of titanium nitride (TiN) film, a double-layer laminated film in which a TiN film is provided on a titanium (Ti) film, a triple-layer laminated film made of a Ti film/TiN film/Ti film, a double-layer laminated film in which a TiN film is provided on a titanium silicide film, or a triple-layer laminated film made of titanium silicide film/TiN film/titanium silicide film. Also, instead of the titanium silicide film and titanium nitride film, the aforementioned construction may be achieved by combining a nickel silicide film and a nickel film. In other words, the etching stop film 503 can be a double-layer laminated film in which a nickel film is provided on a nickel silicide film, or a triple-layer laminated film made of nickel silicide film/nickel film/nickel silicide film. Such materials have the property of not being dry-etched in a fluorine-containing plasma.

In a construction wherein an etching stop film 503 as described above is provided, as shown in FIG. 1, a photoresist film 91 is provided on the cover insulating film 514 by a lithographic process and a dry etching process is performed using a fluorine-containing plasma. In this way, etching proceeds successively from the cover insulating film 514 towards the lower films. In this process, as shown in FIG. 1B, in the peripheral circuit region, the etching stop film 503 is not etched away by etching using fluorine-containing plasma, so the etching stops at the stage where the upper surface of the etching stop film 503 is exposed.

After this, as shown in FIG. 1C, the upper surface of the first silicon film 502 is exposed by etching the etching stop film 503 by a dry etching process using as the etching gas for example a chlorine-containing plasma originating from a gas such as chlorine gas (Cl₂), boron trichloride gas (BCl₃), or carbon tetrachloride gas (CCl₄).

Next, by a dry-etching process using fluorine-containing plasma as in FIG. 1B, etching can be stopped on the gate-insulating film 501 by etching the first silicon film 502, which is constituted by a single-layer film.

Also, there is no possibility of insufficient etching in the memory cell region, where the etching rate is low, since the laminated film on the semiconductor substrate 100 allows ample over-etching while etching of the peripheral circuit region is stopped by the etching stop layer 503. Also, even if over-etching takes place in the memory cell region, no adverse effects on the device properties can occur.

As described above, in one example of a method of manufacturing a semiconductor device according to the present invention, the gate electrodes of the transistors constituting the second region (peripheral circuit region) are constituted by a laminated film consisting of a first silicon film that is formed on the gate insulating film, an etching stop film, and a second silicon film. Consequently, even though etching of the laminated film for the gate electrodes proceeds successively from the upper layer towards the lower layers, etching is stopped by the etching stop film, so there is no possibility of continued etching of the first silicon film occurring. As a result, after the etching stop film has been etched, the first silicon film can be etched independently as a single-layer film, so, in the peripheral circuit region (second region), the problem of excessive etching of the gate insulating film and, finally, of the semiconductor substrate can be avoided.

Also, since the etching stop film is present between the first and second polysilicon films, no interface of the first and second polysilicon films exists. The problem of generation of an intervening layer that interferes with dry etching at the interface of the first and second polysilicon films, causing silicon residue to be produced, can therefore be obviated.

Furthermore, an etching stop film, acting as an etching stopper, is formed as an under-layer to the second silicon film even if a third silicon film is formed on the second silicon film, producing a laminated condition of the second and third silicon films. Ample over-etching of the second and third silicon films can therefore be performed, avoiding the problem of generation of etching residue of these films.

Practical examples of application of the present invention are described below with reference to the drawings. These practical examples are merely specific examples given to enable an even deeper understanding of the present invention and it is not intended that the present invention should be restricted to these specific examples in any way. Also, equivalent members are given the same reference symbols and further description thereof is dispensed with or abbreviated; equivalent members are not given respective reference symbols. It should be noted that the drawings employed in the following description are diagrammatic only and the ratios of length, width and thickness in these drawings are not necessarily the same as in an actual article: furthermore, the ratios of length, width and thickness in the various drawings, as well as shading etc. may not coincide. In the following practical examples, conditions such as the specifically illustrated materials and dimensions are merely given by way of example.

It should be noted that, in the following practical examples, the “first region” and “second region” referred to in the claims respectively correspond to the memory cell region and peripheral circuit region. The “first wiring” and “second wiring” in the claims respectively correspond to the bit lines 500A and third gate electrodes 500B.

### First Embodiment

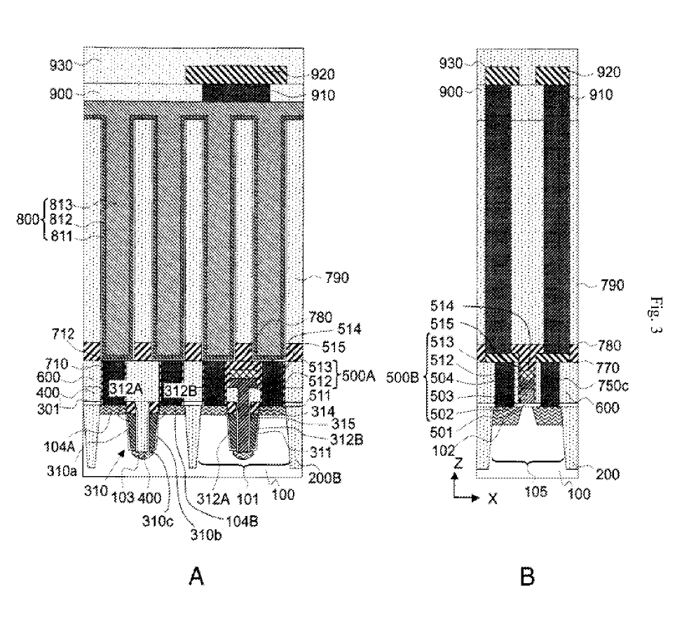

A semiconductor device according to this embodiment is described below with reference to FIGS. 2 and 3. FIG. 2 is a plan view showing diagrammatically an example of the layout of a DRAM constituting a semiconductor device according to this embodiment. FIG. 3A is a cross-sectional view along the line A-A′ in FIG. 2. The line A-A′ indicates a broken-line cross-section, in which the left hand side of the Figure is a cross-section that does not contain the bit line contact plugs 511, whereas the right-hand side is a cross-section that does contain the bit line contact plugs 511. FIG. 3B shows the cross-section of the peripheral circuit region along B-B′.

First of all, the arrangement of the major portions of a semiconductor device according to the present embodiment will be described with reference to the plan view of FIG. 2. The semiconductor device 1 constitutes a DRAM having a memory cell region (first region) 2 on a semiconductor substrate 100, and a peripheral circuit region (second region) 3 arranged around the first region. It should be noted that, in the plan view of FIG. 2, the inter-layer insulating film or capacitor that is formed above the bit lines (first wiring) 500A is omitted in order to facilitate understanding of the drawings. In this embodiment, the semiconductor substrate 100 is described as being a p-type silicon monocrystal, but there is no restriction to this and an n-type silicon monocrystal or TFT silicon substrate or the like could be employed.

The memory cell region 2 has island-shaped active regions 101 constituted by the semiconductor substrate 100, that are isolated in the X′ direction by first element isolating regions 200A extending in the X′ direction (third direction), which is inclined with respect to the X direction (second direction), and second element isolating regions 200B extending in the Y direction (first direction), which is a direction that is perpendicular to the X direction. It should be noted that, although, in FIG. 2, the active regions 101 are indicated by parallelograms having long sides in the X′ direction, the shape of the active regions 101 is not restricted to this and they could be of oblong shape constituted by rounding of the four corners of the parallelograms. Furthermore, the active regions 101 are disposed in a repetitive arrangement in the X′ direction and Y direction with equal pitch intervals. There is no particular restriction regarding the interval of arrangement of adjacent active regions 101 in the Y direction: this could be the same as the width of the active regions 101 in the Y direction, or could be a dimension smaller than this.

A plurality of first word trenches 310 that extend linearly in the Y direction are arranged spanning a plurality of first element isolating regions 200A and a plurality of active regions 101. The ends of the first word trenches 310 in the Y direction are positioned within the element isolating region 200 constituting the peripheral circuit region 3. Lower diffusion layers, to be described, are provided in the respective active regions 101, in contact with the bottom face of the first word trenches 310, providing a bit line contact connection region 7. The side faces facing the X direction of the first word trenches 310 and extending in the Y direction constitute a first side face 310a and second side face 310b. First buried word lines 300A that extend in the Y direction are arranged at the first side faces 310a, but with interposition of a first gate insulating film therebetween. Also, second buried word lines 300B that extend in the Y direction are arranged at the second side faces 310b, but with interposition of the first gate insulating film therebetween. Specifically, in the semiconductor device 1 of the present embodiment, a single first word trench 310 running in the Y direction is arranged within a single active region 101 and respective wirings are arranged at the side faces facing the X direction within the single first word trench 310. It should be noted that the first embedded word line 300A, as will be described, functions as a gate electrode of the corresponding transistor and includes first cell gate electrodes. Likewise, the second embedded word line 300B includes second cell gate electrodes.

The active region 101 constituting the bottom face of the first word trench 310 is sandwiched by the first embedded word line 300A and the second embedded word line 300B and constitutes a bit line contact connection region 7. A bit line contact plug 511 is arranged in the respective bit line contact connection regions 7. A bit line 500A that extends linearly in the X direction (second direction) is arranged so as to connect a plurality of bit line contact plugs 511 arranged in the X direction.

The portion of the active region 101 that is adjacent, with the first gate insulating film intervening, to the first embedded word line 300A that is positioned at the side face of the first word trench 310 constitutes a first capacitance contact connection region 8A. A first upper diffusion layer, to be described, is provided at the upper portion thereof, including the upper face of the first capacitance contact connection region 8A. A first capacitance contact plug 700A is arranged between bit lines 500A that are adjacent in the Y direction, including the first capacitance contact connection region 8A. Also, likewise, the active region 101 that is adjacent to the second embedded word line 300B constitutes a second capacitance contact connection region 8B. A second upper diffusion layer, to be described, is provided in the upper portion thereof, including the upper face of the second capacitance contact connection region 8B. A second capacitance contact plug 700B is arranged between bit lines 500A that are adjacent in the Y direction, including the second capacitance contact connection region 8B. The aforementioned first capacitance contact connection region 8A constitutes a first silicon pillar (first semiconductor pillar) wherein, as will be described, the first element isolating region 200A contacts the two side faces thereof facing the Y direction, the two element isolating regions 200B contact one side face thereof facing the X direction, and a first gate insulating film contacts the other side face (first side face 310a) thereof. Likewise, the second capacitance contact connection region 8B constitutes a second silicon pillar (second semiconductor pillar).

A first vertical type cell transistor 4A whose channel is constituted by the first side face 310a of the first word trench 310 is constituted by the aforementioned first upper diffusion layer, the first gate insulating film, the first embedded word line 300A, and the lower diffusion layer 103 (not shown in FIG. 2). Also, a second vertical type cell transistor 4B whose channel is constituted by the second side face 310b of the first word trench 310 is constituted by the second upper diffusion layer, the first gate insulating film, the second embedded word line 300B, and the lower diffusion layer 103. The lower diffusion layer 103 is arranged to be shared by the two vertical type cell transistors 4A, 4B.

Next, the peripheral circuit region 3 will be described. A plurality of peripheral circuit active regions 105 surrounded by an element isolating region 200 are arranged in the peripheral circuit region 3 that is arranged adjacent to the memory cell region 2 in the X direction. It should be noted that the shape, number and arrangement of the peripheral circuit active regions 105 are not restricted to those shown in FIG. 2. Third gate electrodes (second wiring) 500B are arranged, with an intervening second gate insulating film, directly above the center of the peripheral circuit active regions 105 in the X direction. In FIG. 2, the third gate electrodes 500B extend in the Y direction so as to cut across the middle of the peripheral circuit active regions 105, a plurality of which are arranged in the Y direction; however, such an arrangement of the third gate electrodes 500B is not necessarily essential. A source/drain diffusion layer 102 is arranged in the peripheral circuit active region 105 that is adjacent to the third gate electrode 500B in the X direction, and is electrically connected by means of a contact plug 750c of the peripheral transistor with a peripheral circuit wiring 770 (not shown) that is provided as an upper layer. Peripheral circuit transistors 5 are constituted by third gate electrodes 500B, the two source/drain diffusion regions 102 and the second gate insulating film.

Next, the cross-sectional view of FIG. 3A will be referred to. A first word trench 310 that runs in the Y direction, spanning a plurality of active regions 101 and a plurality of first element isolating regions 200A that are lined up in the Y direction is provided extending in the X′ direction. The first word trench 310 comprises a first side face 310a, a bottom face 310c, and a second side face 310b. First cell gate electrodes 312A are arranged on the first side face 310a, with an intervening first gate insulating film 311. A lower diffusion layer 103 is provided over the entire middle portion of the bottom face 310c in the Y direction, in the active region 101 constituting the bottom face 310c. The bottom of the lower diffusion layer 103 is formed thinner than the thickness of the second element isolating region 200B. Second cell gate electrodes 312B are arranged, with a first gate insulating film 311 interposed, on the second side face 310b.

The active region 101 facing the first cell gate electrodes 312A through the first gate insulating film 311 constitutes the first capacitance contact connection region 8A and constitutes a first semiconductor pillar, as described above. A first upper diffusion layer 104A is provided at the top thereof, including the upper face of the first semiconductor pillar. Also, the active regions 101 facing the second cell gate electrodes 312B through the first gate insulating film 311 constitutes the first capacitance contact connection regions 8B, and constitutes second semiconductor pillars. A second upper diffusion layer 104B is provided at the top, including the upper surface of the second semiconductor pillars. First vertical cell transistors are constituted by the first upper diffusion layer 104A, the first gate insulating film 311, the first cell gate electrodes 312A constituted by the first embedded word line 300A, and the lower diffusion layer 103. Also, the second vertical cell transistor is constituted by the second upper diffusion layer 104B, the first gate insulating film 311, the second cell gate electrodes 312B constituted by the second embedded word line 300B, and the lower diffusion layer 103. A cap insulating film 314 is arranged in contact with the upper surfaces of the first cell gate electrodes 312A and the second cell gate electrodes 312B. The first upper diffusion layer 104A and the second upper diffusion layer 104B respectively constitute one of the source/drain, while the lower diffusion layer 103, which is shared by two transistors, constitutes the other of the source/drain. A lower diffusion layer 103 of n type impurity concentration 1×10²⁰ to 1×10²¹ (atoms/cm³) adjoins the bottom face 310c of the first word trench 310.

A new second word trench 316 that extends in the Y direction is constituted by arranging the first embedded word line 300A and second embedded word line 300B within the first word trench 310 that extends in the Y direction, as shown in FIG. 2. In the second word trench 316, there are formed bit line contact plugs 511 that are connected with the lower diffusion layer 103 by passing through the side wall insulating film 315, that extends in the Y direction of the second word trench 316. It should be noted that, in FIG. 2, the spaces between the plurality of bit line contact plugs 511 that are adjacently arranged in the Y direction within the second word trench 316 are buried by the first interlayer insulating film 400.

At the upper surface of the semiconductor substrate 100, there is provided a laminated film consisting of a pad insulating film 301 and the first interlayer insulating film 400, having an upper surface that is coplanar with the upper surface of the cap insulating film 314 and the upper surfaces of the bit line contact plugs 511. The pad insulating film 301 is the same as the second gate insulating film 501 of the peripheral circuit region 3, to be described. Bit lines (first wiring) 500A extending in the X direction (see FIG. 1A) are provided at the upper surface of the cap insulating film 314 and the upper surface of the first interlayer insulating film 400, and are connected with a plurality of bit line contact plugs 511. The bit lines 500A have a laminated structure, comprising a first conductive film 512 and second conductive film 513. A cover insulating film 514 is provided at the upper surface of the bit lines 500A, and a sidewall insulating film 515 is provided so as to cover the side faces of the bit lines 500A and the cover insulating film 514. A second interlayer insulating film 600 is arranged on the entire surface, so as to cover the side wall insulating film 515.

The first upper diffusion layer 104A and the second upper diffusion layer 104B (hereinbelow, the first upper diffusion layer 104A and the second upper diffusion layer 104B will be referred to jointly as the upper diffusion layer 104) are exposed at the bottom of capacitance contact holes 710: these capacitance contact holes 710 are formed passing through the second interlayer insulating film 600. Contact plugs 712 are arranged within the capacitance contact holes 710 and are connected with the upper surface of the upper diffusion layer 104. A third interlayer insulating film 790 and stop film 780 are arranged on the entire surface of the semiconductor substrate 100, including the upper surface of the capacitance contact plugs 712. Capacitance lower electrodes 811 that pass through the third interlayer insulating film 790 and stop film 780 are connected with the upper surfaces of the capacitance contact plugs 712. A capacitance insulating film 812 and capacitance upper electrodes 813 are provided so as to cover the capacitance lower electrodes 811, thereby constituting cylinder-type capacitors 800.

Next, we shall refer to FIG. 3B. FIG. 3B shows a cross-section along the line B-B′ of the peripheral circuit region 3 shown in FIG. 2. Directly above the central portion of the peripheral circuit active region 105 that is surrounded by the element isolating region 200, there are provided third gate electrodes (second wiring) 500B constituted by successively laminating silicon oxide film and high dielectric constant film or the second gate insulating film 501 that consists of a laminated film of silicon oxide film or high dielectric constant film, the first silicon film 502, the etching stop film 503, the second silicon film 504, the first conductive film 512 and the second conductive film 513. A cover insulating film 514 is provided on the third gate electrodes 500B. The position of the uppermost surface of the laminated film comprising the first conductive film 512 and second conductive film 513 in the direction perpendicular to the semiconductor substrate surface is adjusted by the total film thickness of the first silicon film 502, the etching stop film 503 and the second silicon film 504 so as to be the same as the position in the direction perpendicular to the semiconductor substrate surface of the uppermost surface of the laminated film consisting of the first conductive film 512 and second conductive film 513 of the memory region 2. In the prior art, in the peripheral circuit region, only the first silicon film 300 and second silicon film 78A were arranged between the metal film 79 and the gate insulating film 501, but, in the present embodiment, a three-layer construction is constituted comprising the first silicon film 502, the etching stop film 503 and the second silicon film 504. A sidewall insulating film 515 is provided so as to cover the side faces of the third gate electrodes 500B and, in addition, a second interlayer insulating film 600 is provided. The contact plugs 750c are connected through the second interlayer insulating film 600, sidewall insulating film 515 and second gate insulating film 501 with the upper surface of a peripheral contact connection region constituted by the peripheral circuit active regions 105. A peripheral wiring 770 is arranged so as to be connected with the upper surface of the contact plug 750c. A third interlayer insulating film 790 and a stop film 780 are provided so as to cover the peripheral wiring 770.

In the memory cell region 2, a fourth interlayer insulating film 900 is provided so as to cover the capacitor 800 and, in the peripheral circuit region 3, so as to cover the stop film 780 and third interlayer insulating film 790. Next, in the case of the memory cell region 2, wiring contacts 910 are provided that are connected with upper electrodes 813 through the fourth interlayer insulating film 900, and, in the case of the peripheral circuit region 3, that are connected with the peripheral wiring 770 through the fourth interlayer insulating film 900, the stop film 780 and the third interlayer insulating film 790. Wiring 920 so as to effect connection with the wiring contacts 910 is respectively provided in the memory cell region 2 and the peripheral circuit region 3; in addition, a protective insulating film 930 is provided on the fourth interlayer insulating film 900.

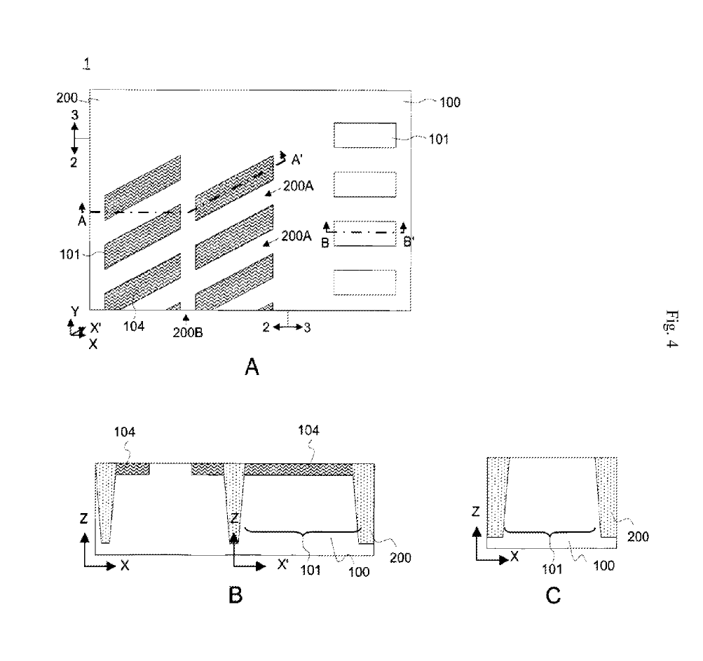

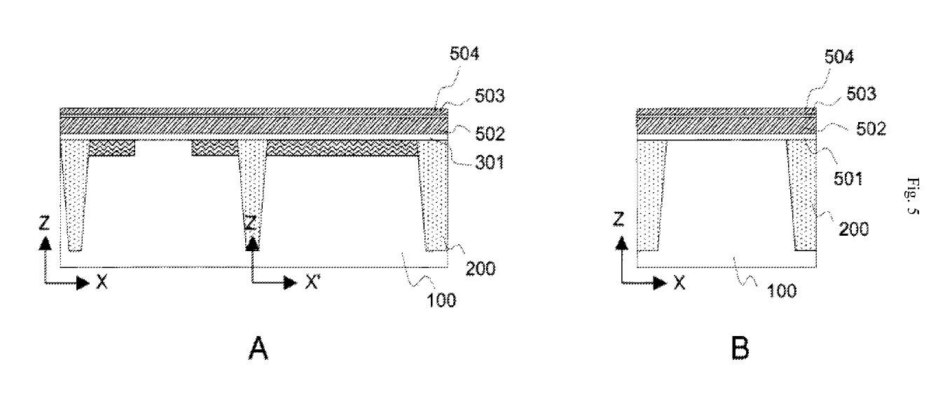

Next, a method of manufacturing a semiconductor device according to the embodiment described above will be described with reference to FIG. 2 to FIG. 17. FIG. 4A is a view corresponding to the plan view shown in FIG. 2; FIG. 4B is a view corresponding to the cross-sectional view along the line A-A′ shown in FIG. 3A; and FIG. 4C is a view corresponding to the cross-sectional view along B-B′ shown in FIG. 3B. Also, in FIGS. 5 to 17, FIG. A is a view corresponding to the cross-sectional view along the line A-A′ shown in FIG. 3A, and FIG. B is a view corresponding to the cross-sectional view along the line B-B′ shown in FIG. 3B.

First of all, FIG. 4A, FIG. 4B and FIG. 4C will be described. An element isolating region is formed on a semiconductor substrate 100 made of p type monocrystalline silicon, using the known STI (shallow trench isolation) method of formation. Specifically, a first element isolating region 200A and second element isolating region 200B are formed in the memory cell region 2, while an element isolating region 200 is formed in the peripheral circuit region 3. In this way, a plurality of active regions 101 constituted by the semiconductor substrate 100 are formed respectively in the memory cell region 2 and the peripheral circuit region 3. Next, by a lithographic process, the peripheral circuit region 3 is covered with a photoresist mask (not shown) and an n type impurity diffusion layer 104 is formed, using ion implantation, in the vicinity of the upper surface of the active regions 101 within the memory cell region 2. The n type impurity diffusion region 104 is the region that will constitute the upper diffusion layer of the vertical transistors in the next step.

Next, as shown in FIG. 5A and FIG. 5B, a second gate insulating film 501 constituted by an oxide film, a first polysilicon film 502, and etching stop film 503 constituted by a composite film of titanium (Ti) film/titanium nitride (TiN) film/titanium (Ti) film, and a second polysilicon film 504 are deposited, in that order, on the entire surface of the semiconductor substrate 100. In the case of the memory cell region 2, the second gate insulating film 501 will now be referred to as the mat insulating film 301. Also, although, in the present embodiment, the second gate insulating film 501 (mat insulating film 301) was described as being an oxide film of thickness about 5 nm, it could be made of a high dielectric constant film (high-K film) having a dielectric constant higher than that of silicon oxide, or of a composite film of silicon oxide and high-K film. The total thickness of the first polysilicon film 502, etching stop film 503 and second polysilicon film 504 is adjusted so as to be equal to the thickness of the first interlayer insulating film, to be described. In this embodiment, it is assumed that the thickness of the first interlayer insulating film, to be described, is 20 nm, the thickness of the first polysilicon film 502 is 10 nm, the thickness of the etching stop film 503 is 5 nm (titanium film/titanium nitride film/titanium film=1 nm/3 nm/1 nm), and the thickness of the second polysilicon film 504 is 5 nm.

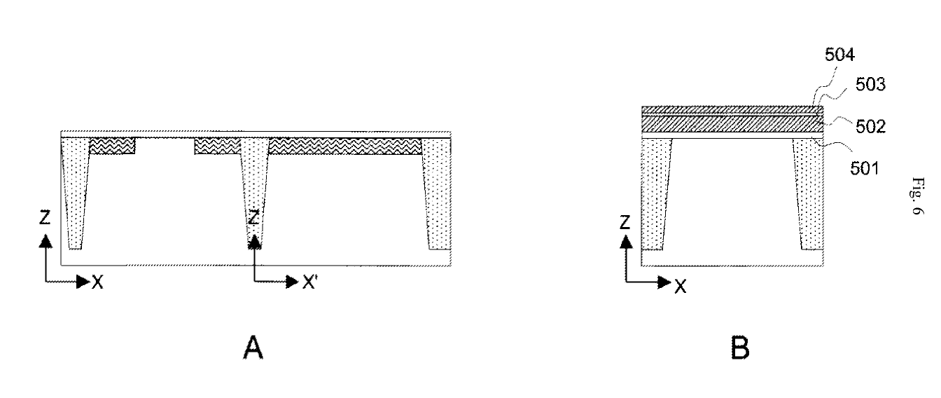

Next, as shown in FIG. 6A and FIG. 6B, the first polysilicon film 502, etching stop film 503 and second polysilicon film 504 of the memory cell region 2 are removed by a lithographic process and dry etching process.

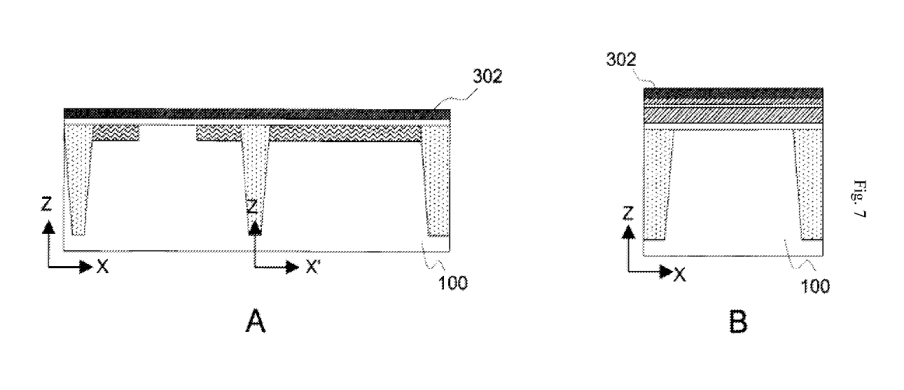

Next, as shown in FIG. 7A and FIG. 7B, a mask film 302 is formed on the entire surface of the semiconductor substrate 100. The mask film 302 is a multilayer film having a photoresist as the uppermost layer, and including for example an amorphous carbon film.

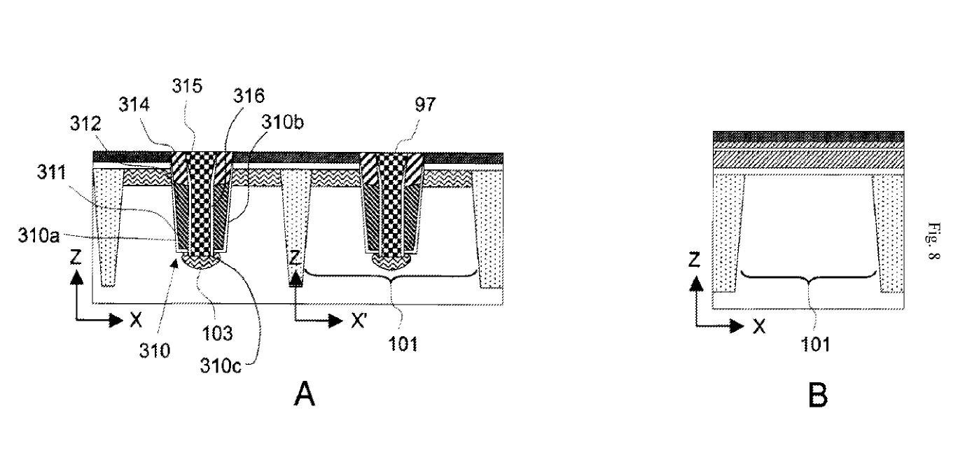

Next, as shown in FIG. 8A and FIG. 8B, by the known methods, a first word trench 310 of thickness for example 150 nm is formed and, in the active regions 101 adjoining the bottom 310c thereof, there are formed: a lower diffusion layer 103; a first embedded word line 300A (see FIG. 2) comprising a first gate insulating film 311 at the first side face 310a thereof, a metal word line 312, a cap insulating film 314 and a sidewall insulating film 315; and a second embedded word line 300B (see FIG. 2) of the same construction as the second side face 310b: a BARC 97 is embedded in the remaining second word trench 316 portion.

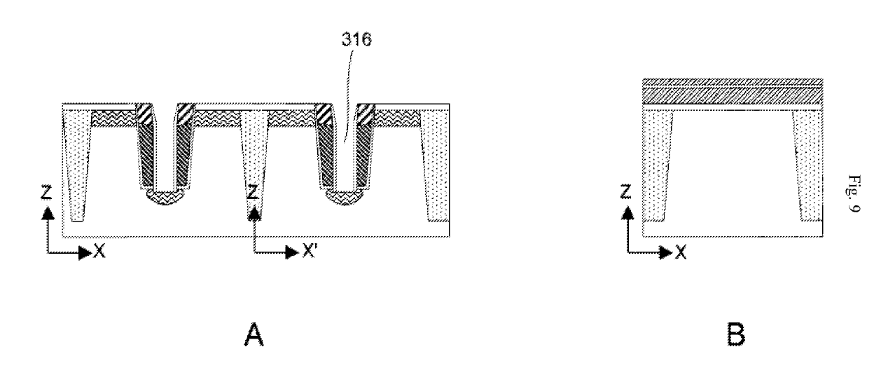

Next, as shown in FIG. 9A and FIG. 9B, the mask film 302 is removed by ashing or the like. At this point, the BARC 97 that is buried in the second word trench 316 portion is simultaneously removed.

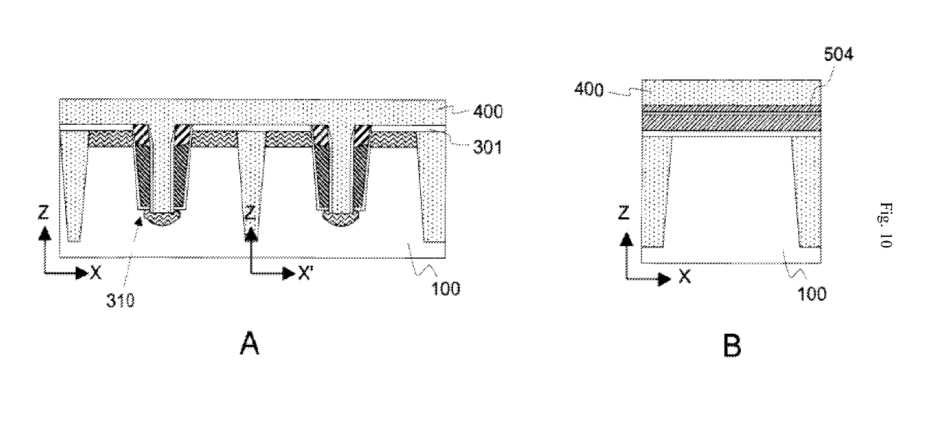

Next, as shown in FIG. 10A and FIG. 10B, on the entire surface of the semiconductor substrate 100 including the remaining first word trench 310 portion, in the case of the memory region 2, a first interlayer insulating film 400 of about 20 nm is formed on the mat oxide film 301 and, in the case of the peripheral circuit region 3, is formed on the second polysilicon film 504; the remainder of the first word trench 310 portion is thereby buried.

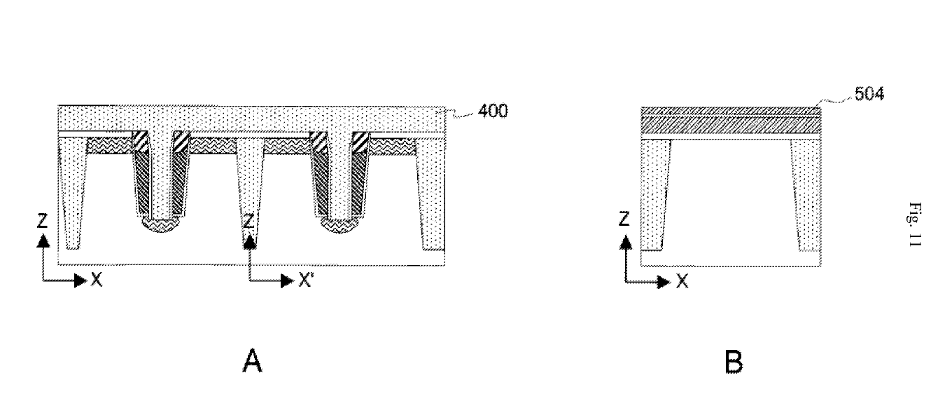

Next, as shown in FIG. 11A and FIG. 11B, the first interlayer insulating film 400 of the peripheral circuit region 3 is removed by lithographic processing and dry etching processing. In this way, the upper surface of the first interlayer insulating film 400 of the memory cell region 2 and the upper surface of the second polysilicon film 504 of the peripheral circuit region 3 are made coplanar.

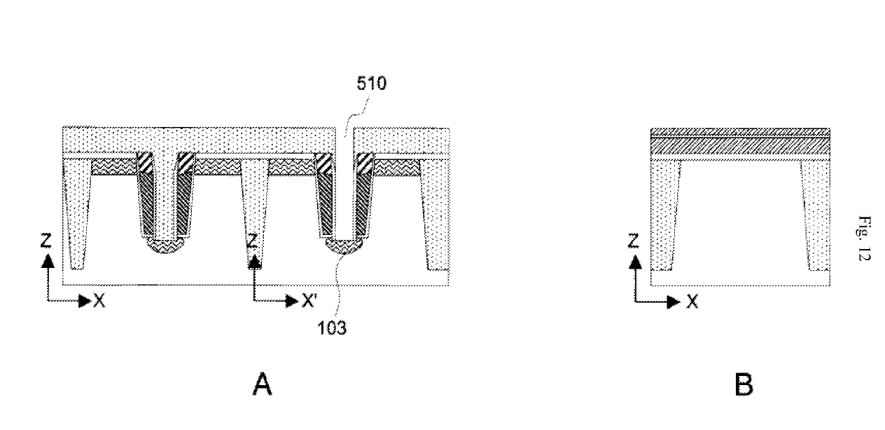

Next, as shown in FIG. 12A and FIG. 12B, bit contact holes 510 are formed by the known method. The lower diffusion layer 103 is exposed at the bottom surface of the bit contact holes 510.

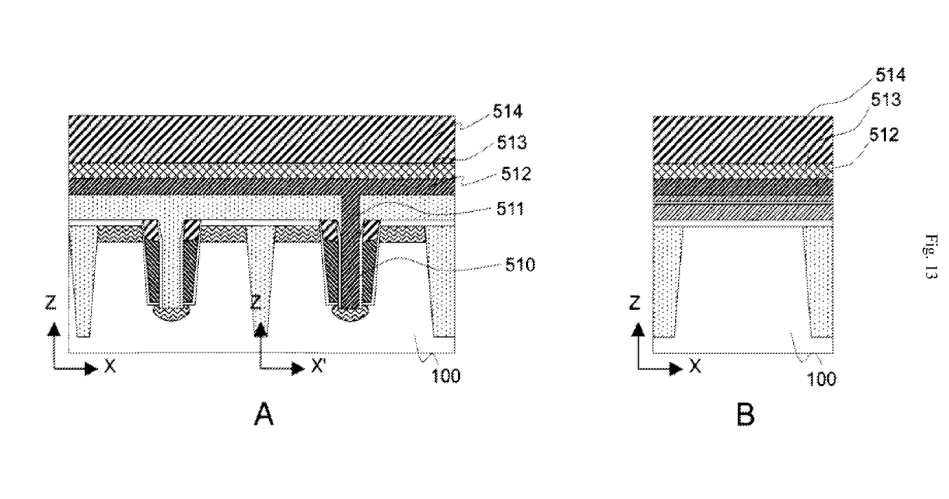

Next, as shown in FIG. 13A and FIG. 13B, the first conductive film 512, the second conductive film 513 and cover insulating film 514 are formed, in that order, on the entire surface of the semiconductor substrate 100 so as to bury the bit contact holes 510. Bit contact plugs 511 are constituted by the first conductive film 512 that is embedded in the bit contact holes 510. In this case, the first conductive film 512 may be formed of silicon film containing n type impurity of 1×10²⁰ to 1×10²¹ (atoms/cm³). Also, as will be described, it may be formed of metal film of lower resistance. The second conductive film 513 may be formed of laminated metal comprising a metal silicide film such as titanium silicide, a metal nitride film such as titanium nitride, tungsten silicide film, and a tungsten film, in that order from the bottom. At least the tungsten film is formed using a sputtering technique. Also, the cover insulating film 514 may be formed of silicon nitride film formed by a CVD process.

As described above, in the present embodiment, an example was described wherein the first conductive film 512 including the bit contact plugs 511 was formed of silicon film, while the second conductive film 513 was formed of metal film. However, the material of the bit contact plugs 511 is not restricted to this and the bit contact plugs 511 could also be formed by a metal film.

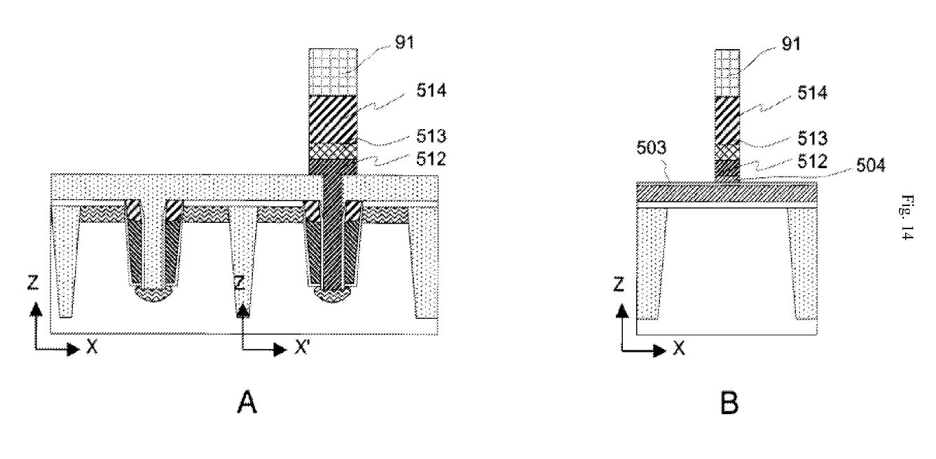

Next, as shown in FIG. 14A and FIG. 14B, a photoresist pattern 91 is formed on the cover insulating film 514 of the memory cell region 2 and the peripheral circuit region 3 by lithographic processing. By a dry etching process using the photoresist pattern 91 as a mask, the cover insulating film 514, the second conductive film 513 and the first conductive film 512 that are positioned in the memory cell region 2, and the cover insulating film 514, the second conductive film 513, the first conductive film 512 and the second polysilicon film 504 that are positioned in the peripheral circuit region are successively etched. In this dry etching, a Ti/TiN/Ti film is used as an etching stop film: in other words, etching is performed under conditions of high selectivity ratio of polysilicon with respect to Ti/TiN/Ti. Specifically, reactive ion etching is performed using a fluorine-containing plasma originating from a gas such as sulfur hexafluoride gas (SF₆), carbon tetrafluoride gas (CF₄) or trifluoromethane gas (CHF₃).

In this embodiment, in the step of FIG. 13A and FIG. 13B, a laminated film of the first polysilicon film 502, the etching stop film 503, and the second polysilicon film 504 is formed in the peripheral circuit region. Consequently, even though etching of the second polysilicon film 504 proceeds well, etching is stopped by the etching stop film 503, so there is no possibility of etching being continued into the first silicon film 502. As a result, the first silicon film 502 can be independently etched as a single-layer film after etching of the etching stop film 503; the problem of excessive etching of the second gate insulating film 501 and, finally, of the semiconductor substrate 100 can thereby be obviated. Specifically, in this embodiment, even if, as a result of miniaturization, a difference in etching rate of the laminated films in the memory cell region 2 and the peripheral circuit region 3 is produced, such a difference in etching rate can be absorbed by etching delay produced by the etching stop film 503. Consequently, etching through the second gate insulating film 501 does not occur, so substrate damage is unlikely.

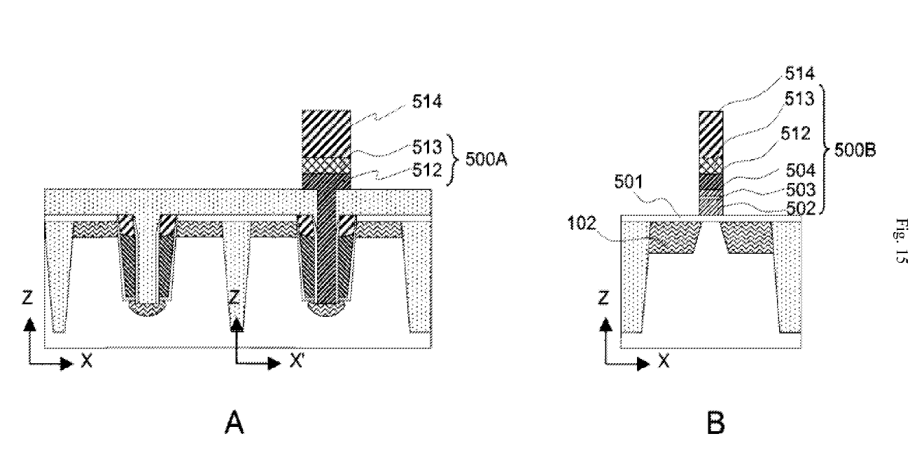

Next, as shown in FIG. 15A and FIG. 15B, etching of the etching stop film 503 (Ti/TiN/Ti) is performed. This time, as the etching conditions of the etching stop film 503, plasma etching using a chlorine-based gas, such as chlorine gas (Cl₂), boron trichloride gas (BCl₃), or carbon tetrachloride gas (CCl₄) are specified. The first polysilicon film 502 that is positioned in the peripheral circuit region 3 is etched by a lithographic technique and dry etching technique of the polysilicon film. For the etching conditions of the first polysilicon film 502, the same conditions as in the case of etching of the second polysilicon film 504 in FIGS. 14A and 14B can be specified.

It should be noted that, in this embodiment, no interface positioned between the first polysilicon film 502 and the second polysilicon film 504 is present. The problem of generation of polysilicon film etching residue caused by the production of an etching-impeding intervening layer at the interface of the first polysilicon film 502 and the second polysilicon film 504 can therefore be obviated.

In this way, bit lines 500A are formed that extend in a straight line in the X direction and are connected with the upper surface of the bit contact plugs 511 in the memory cell region. Also, in the peripheral circuit region 3, there are formed third gate electrodes 500B of polymetal construction, comprising the second conductive film 513 formed on the upper surface of the second gate insulating film 501, the first conductive film 512, the second polysilicon film 504, the etching stop film 503 and the first silicon film 502.

Next, after protecting the memory cell region 2 by a photoresist by a lithographic technique, n type impurity such as for example phosphorus or arsenic is implanted through the second gate insulating film 501 using an ion implantation technique, to form the source/drain diffusion layer 102 of the peripheral circuit region.

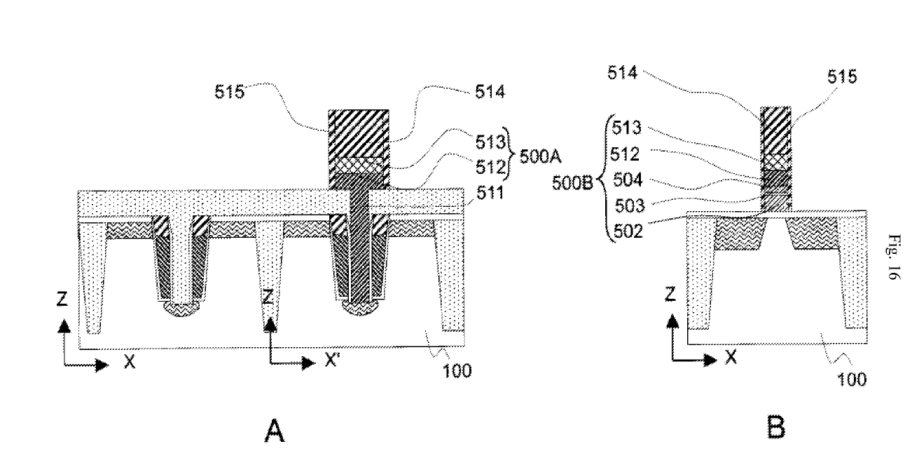

Next, as shown in FIG. 16A and FIG. 16B, a silicon nitride film of thickness about 10 nm is formed over the entire surface of the semiconductor substrate 100, so as to cover the bit lines 500A and the cover insulating film 514 thereupon, of the memory cell region 2, and the third gate electrodes 500B and the cover insulating film 514 thereupon, of the peripheral circuit region 3. In addition, a sidewall insulating film 515 is formed by etching-back, leaving only the side faces of the bit lines 500A and the cover insulating film 514 thereupon, and the third gate electrodes 500B and cover insulating film 514 thereupon.

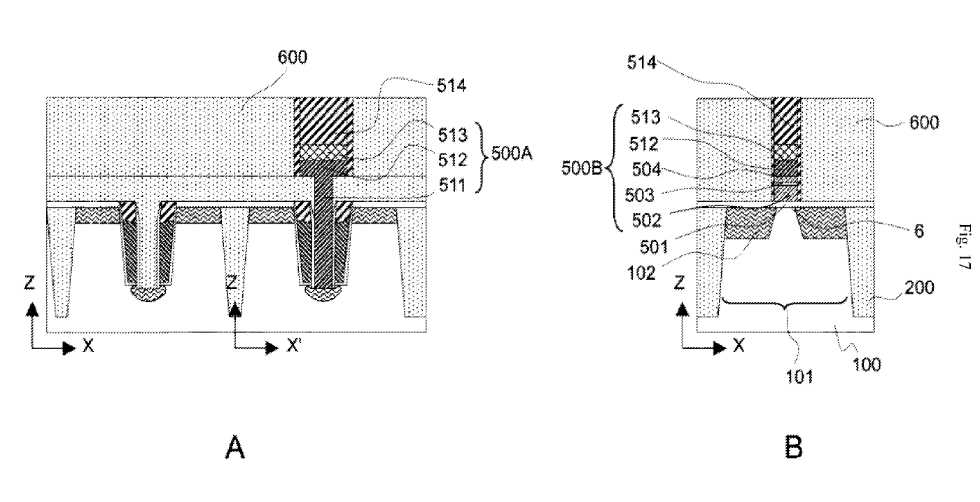

Next, as shown in FIG. 17A and FIG. 17B, a coating film containing polysilane is formed over the entire surface, so as to bury the convex portions constituted by the bit lines 500A and the cover insulating film 514 thereupon, and the third gate electrodes 500B and the cover insulating film 514 thereupon. After this, the second interlayer insulating film 600 is formed by reforming the polysilane to silicon oxide film by heat treatment in an oxidizing atmosphere. Next, the surface of the second interlayer insulating film 600 is flattened by the CMP method.

Next, as shown in FIG. 3A and FIG. 3B, the semiconductor device 1 according to the present embodiment as shown in FIG. 2 to FIG. 3 can be formed by known methods, by a step of forming capacitance contact plugs 700 and contact plugs 750c of the memory cell region, a step of forming the peripheral wiring 770, a step of forming the stop film 780 and the third interlayer insulating oxide film 790, a step of forming capacitors 800, a step of forming the fourth interlayer insulating oxide film 900, a step of forming the wiring contact plugs 910 and wiring 920, and a step of forming the protective insulating film 930.

### Explanation of the Reference Symbols

1 Semiconductor device
2 Memory cell region
3 Peripheral circuit region
4A, 4B Vertical cell transistors
5 Peripheral circuit transistors
7 Bit line connection region
8A First capacitance contact connection region
8B Second capacitance contact connection region
75 Interlayer insulating film
78A, 78B Silicon films
79 Tungsten film
80 Silicon nitride film
91 Photoresist
100 Semiconductor substrate
101 Active regions
102 Source/drain diffusion layer
103 Lower diffusion layer
104 Upper diffusion layer
104A First upper diffusion layer
104B Second upper diffusion layer
105 Active regions
200 Element isolating region
200A First element isolating region
200B Second element isolating region
300 Embedded word lines
300A First embedded word lines
300B Second embedded word lines
301 Mat insulating film
302 Mask insulating film
310 First word trench
310a First side face
310b Second side face
310c Bottom
311 First gate insulating film
312 Metal word lines
312A First cell gate electrodes
312B Second cell gate electrodes
314 Cap insulating film
315 Sidewall insulating film
316 Second word trench
400 First interlayer insulating film
500A Bit lines
500B Third gate electrodes
501 Second gate insulating film
502 First polysilicon film
503 Etching stop film
504 Second polysilicon film
510 Bit contact holes
511 Bit line contact plugs
512 First conductive film
513 Second conductive film
514 Cover insulating film
515 Sidewall insulating film
600 Second interlayer insulating film
700A, 700B Capacitance contact plugs
710 Capacitance contact holes
711 Protective insulating film
712 Capacitance contact plugs
750c Contact plugs
770 Peripheral wiring
780 Stop film
790 Third interlayer insulating film
800 Capacitors
811 Lower electrodes
812 Capacitance insulating film
813 Upper electrodes
900 Fourth interlayer insulating film
910 Wiring contacts
920 Wiring
930 Protective insulating film

1. A semiconductor device comprising:
a semiconductor substrate;
a first wiring having, in this order, on a first region of said semiconductor substrate, a second silicon film containing impurity, and a conductive film; and
a second wiring having, in this order, on a second region of said semiconductor substrate, a first silicon film containing impurity, an etching stop film, a second silicon film containing impurity, and a conductive film.

2. The semiconductor device of claim 1, wherein said etching stop film is any one film selected from the following:
a single-layer film of titanium nitride film;
a laminated film of titanium film and titanium nitride film on said titanium film;
a laminated film of titanium film, titanium nitride film on said titanium film, and titanium film on said titanium nitride film;
a laminated film of titanium silicide film and titanium nitride film on said titanium silicide film;
a laminated film of titanium silicide film, titanium nitride film on said titanium silicide film, and titanium silicide film on said titanium nitride film;
a laminated film of nickel silicide film and nickel film on said nickel silicide film; and
a laminated film of nickel silicide film, nickel film on said nickel silicide film, and nickel silicide film on said nickel film.

3. The semiconductor device of claim 1, wherein said conductive film comprises:
a first conductive film provided on said second silicon film; and
a second conductive film provided on said first conductive film.

4. The semiconductor device of claim 3, wherein said first conductive film is a silicon film containing impurity.

5. The semiconductor device of claim 3, wherein said second conductive film comprises at least one selected from the group consisting of a titanium silicide film, a tungsten silicide film, titanium nitride film, and a tungsten film.

6. The semiconductor device of claim 1, wherein said first region comprises:
an active region;
a first gate insulating film formed on two mutually opposite inside wall side faces of a trench that runs across within said active region in a direction intersecting the direction of extension of said active region;
a first gate electrode formed on one of said inside wall side faces, with said first gate insulating film interposed;
a second gate electrode formed on the other of said inside wall side faces, with said first gate insulating film interposed;
a lower diffusion layer provided within the active region positioned below the bottom of said trench;
a bit line contact plug provided between the first and second gate electrodes within said trench so as to be connected with said lower diffusion layer; and
two upper diffusion layers provided on both sides sandwiching said trench, in said active region.

7. The semiconductor device of claim 6, said first wiring is constituted by bit lines connected with said bit line contact plugs.

8. The semiconductor device of claim 6, wherein said first region further comprises a capacitor electrically connected with said upper diffusion layer.

9. The semiconductor device of claim 1, wherein said second region comprises a planar-type transistor having:
a second gate insulating film provided on said semiconductor substrate; and
a third gate electrode provided on said second gate insulating film as said second wiring.

10. A method of manufacturing a semiconductor device comprising:
forming, in this order, a first silicon film containing impurity and an etching stop film on the second region of said semiconductor substrate;
forming, in this order, a second silicon film containing impurity and a conductive film on the first and second regions of said semiconductor substrate;
forming a first wiring having said second silicon film and conductive film in said first region, by etching the conductive film and said second silicon film of said first and second regions until said etching stop film is exposed;
etching said etching stop film of said second region; and
forming a second wiring having said second silicon film, conductive film, etching stop film and first silicon film in said second region, by etching said first silicon film of said second region.

11. The method of claim 10, wherein forming said first wiring and forming the second wiring, comprises performing said etching using gas selected from the group consisting of sulfur hexafluoride gas (SF₆), carbon tetrafluoride gas (CF₄) and trifluoromethane (CHF₃) gas.

12. The method of claim 10, wherein etching said etching stop film, comprises performing said etching using gas selected from the group consisting of chlorine gas (Cl₂), boron trichloride gas (BCl₃), or carbon tetrachloride gas (CCl₄).

13. The method of claim 10, wherein said etching stop film is any one film selected from the following:
a single-layer film of titanium nitride film;
a laminated film of titanium film and titanium nitride film on said titanium film;
a laminated film of titanium film, titanium nitride film on said titanium film, and titanium film on said titanium nitride film;
a laminated film of titanium silicide film and titanium nitride film on said titanium silicide film;
a laminated film of titanium silicide film, titanium nitride film on said titanium silicide film, and titanium silicide film on said titanium nitride film;
a laminated film of nickel silicide film and a nickel film on said nickel silicide film; and
a laminated film of nickel silicide film, nickel film on said nickel silicide film, and nickel silicide film on said nickel film.

14. The method of claim 10, wherein said conductive film comprises:
a first conductive film provided on said second silicon film; and
a second conductive film provided on said first conductive film.

15. The method of claim 14, wherein said first conductive film is a silicon film containing impurity.

16. The method of claim 14, wherein said second conductive film is at least one film selected from the group consisting of a titanium silicide film, a tungsten silicide film, a titanium nitride film, and a tungsten film.

17. The method of claim 10, comprising, prior to forming said first silicon film and etching stop film:
forming a trench that runs across within said active region in a direction intersecting the direction of extension of an active region of said first region;
forming a first gate insulating film on two mutually facing inside wall side faces of said trench;
forming a first gate electrode and second gate electrode respectively on said two inside wall side faces, with said first gate insulating film interposed;
forming a lower diffusion layer in an active region positioned below the bottom of said trench;
forming a bit line contact plug between the first and second gate electrodes within said trench so as to be connected with said lower diffusion layer; and
forming two upper diffusion layers on both sides sandwiching said trench, in said active region.

18. The method of claim 17, wherein said first wiring is constituted by bit lines connected with said bit line contact plugs.

19. The method of claim 17, wherein, after forming said upper diffusion layer, a capacitor electrically connected with said upper diffusion layer is formed.

20. The method of claim 10, comprising, prior to forming said first silicon film and etching stop film:
forming a second gate insulating film on the semiconductor substrate of said second region; and
said second wiring is constituted by the third gate electrodes of planar-type transistors.
